(19) United States
(12) Patent Application Publication
(10) Pub. No.: US 2014/0070626 A1
(43) Pub. Date: Mar. 13, 2014

(54) Geometries for Placement of Solid State Switch in a Blumlein Assembly

(71) Applicants: Yoko Parker, Pleasanton, CA (US); Kevin Leung, Dublin, CA (US); Antonios Zografos, Oakland, CA (US)

(72) Inventors: Yoko Parker, Pleasanton, CA (US); Kevin Leung, Dublin, CA (US); Antonios Zografos, Oakland, CA (US)

(21) Appl. No.: 13/610,051

(22) Filed: Sep. 11, 2012

(51) Int. Cl. H03K 3/53

(52) U.S. Cl. CPC H03K 3/53
USPC 307/106

(57) ABSTRACT

The geometry of blumleins and how a switch is placed within the blumlein structure are considered. The thicker the switch, the higher the voltage it charged to without breaking down. A thicker switch can also provide a larger surface to illuminate. In one set of exemplary embodiments, the switch modules is displaced to the sides of the of the blumlein structures in a “necking” arrangement, where the switch region curves out a distance to the side. A stack of blumleins can then alternate sides, allowing for the switch region to each have a greater thickness. Another set of exemplary embodiments uses a tab structure: the top, middle and bottom conductors are all straight, but the top and middle conductors each include tabs, between which the switch is placed.

### CROSS-REFERENCE TO RELATED PATENT APPLICATION

This application is related to the concurrently filed entitled “Illumination Techniques for Optically Activated Solid State Switch”, by Fang Huang and Anthony Zografos, which is incorporated herein in its entirety by this reference.

### BACKGROUND

1. Field of the Invention

This application relates generally to high voltage pulse generators, particle accelerators and Blumlein structures, and, more specifically, to the incorporation of switches into such structures.

2. Background Information

Particle accelerators are used to increase the energy of electrically charged atomic particles. In addition to their use for basic scientific study, particle accelerators also find use in the development of nuclear fusion devices and for medical applications, such as cancer therapy. One way of forming a particle accelerator is by use of a dielectric wall type of accelerator, an example of which is described in U.S. Pat. No. 5,757,146, that formed out of one or more Blumlein structures. A Blumlein is basically a set of three conductive layer or strips with the two spaces between the strips being filled with dielectric material to produce a pair of parallel transmission lines: the first transmission line is formed by the top and middle conductive strips and the intermediate dielectric layer; the second transmission line is formed by the bottom and middle conductive strips and the intermediate dielectric layer. The common, middle conductive layer is shared by the pair of lines. By holding the upper and lower conductive layers at ground, charging the shared middle layer to a high voltage, and then discharging the middle layer, a pair of waves then travels down the pair of transmission lines. By arranging for this structure for the waves to produce a pulse at one end, the result field can be used to accelerate a particle beam.

Within these various applications, there is an ongoing need to make particle accelerators more powerful, more compact, or both. Consequently, such devices would benefit from improvements in Blumlein technology.

### SUMMARY OF THE INVENTION

According to a first set of general aspects, a structure comprising one or more blumlein structures is described. Each of the one or more blumlein structures includes a first conductive strip, a second conductive strip, and a third conductive strip. The second conductive strip is positioned between the first and third conductive strips and, outside of a first region, the first, second and third conductive strips are parallel to one another along a first axis. The blumleins also each include a first dielectric and a second dielectric. The second dielectric fills the space between the second and third conductive strips. Each blumlein also includes switch module including a switch having a first terminal and a second terminal respectively connected to the first and the second conductive strips. The first dielectric and the switch module are joined together to fill the space between the first and second conductive strips. The switch is located in the first region between the first and second conductive strips, being displaced sideways relative to the first axis.

Various aspects, advantages, features and embodiments of the present invention are included in the following description of exemplary examples thereof, which description should be taken in conjunction with the accompanying drawings. All patents, patent applications, articles, other publications, documents and things referenced herein are hereby incorporated herein by this reference in their entirety for all purposes. To the extent of any inconsistency or conflict in the definition or use of terms between any of the incorporated publications, documents or things and the present application, those of the present application shall prevail.

### BRIEF DESCRIPTION OF THE DRAWINGS

FIG. 1 shows one exemplary embodiment for a blumlein module.

FIG. 2 is a cross-section view of the central portion of the embodiment of FIG. 1.

FIGS. 3a-c illustrate a number of different interfaces of materials between conductors.

FIGS. 4a and 4b illustrate an embodiment for a switch module assembly.

FIG. 4c shows several possible switch profiles.

FIGS. 5a-d illustrate the placement of the switch module of FIGS. 4a and 4b into the blumlein embodiment of FIGS. 1 and 2.

FIG. 6 shows an alternate embodiment of a switch module.

FIG. 7 shows components of an alternate blumlein embodiment using the switch module of FIG. 6.

FIG. 8 is an enlarged view of the assembled central portion of the embodiment illustrated in FIG. 7.

FIG. 9 illustrates a blumlein structure with a thicker spacing for the top dielectric to accommodate a thicker switch.

FIGS. 10a and 10b show a blumlein with a necking structure for the switch.

FIG. 11 shows a blumlein with a tab structure for the switch.

FIGS. 12 and 13 illustrate some detail for switch illumination.

FIGS. 14-17 show several embodiments that can improve illumination of the switch.

### DETAILED DESCRIPTION

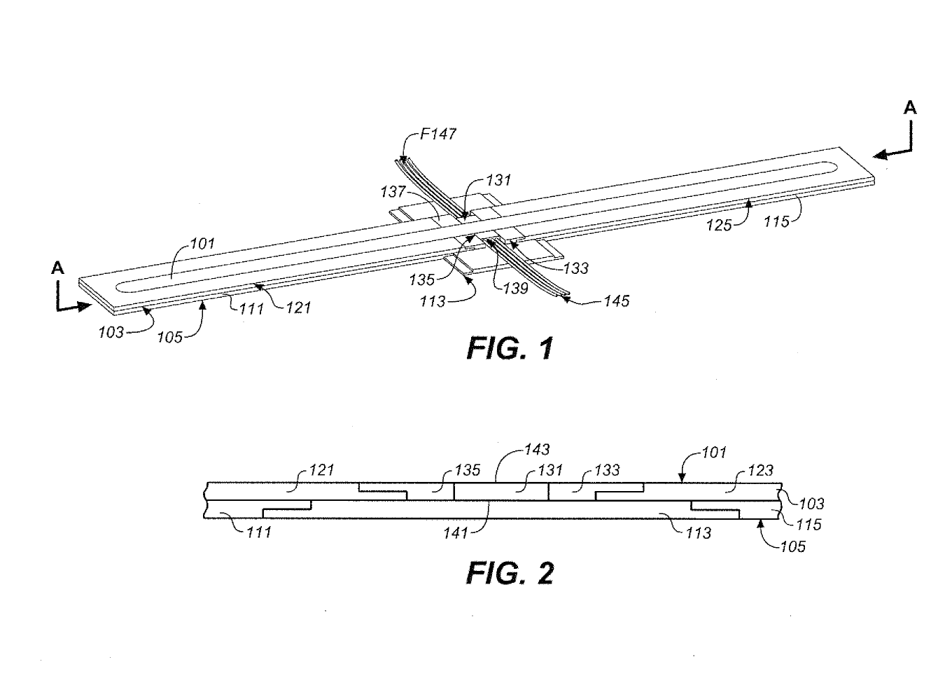

FIG. 1 is a first exemplary embodiment in which the various aspects presented here can be applied. FIG. 2 is a side view of the center portion of a cross-section through the middle of the same embodiment, taken along the axis indicated along A in FIG. 1. Referring first to FIG. 2, the blumlein module is formed a top conducting strip 101, a middle conducting strip 103, and a bottom conducting strip 105 that run parallel from left to right with uniform spacing between each pair. The space between the middle conductive strip 103 and the bottom conductive strip 105 is filled with dielectric material to form the bottom transmission line. Here the dielectric is formed of three components, 111, 113, and 115, for reasons that will be explained below, but in other embodiments this can be a single element. The top transmission line is formed by the top (101) and middle (103) conductive strips with the space in between filled with switch structure or module with dielectric material 121 and 125 on either side. The switch module structure is formed of the switch 131 itself, having electrical contacts 143 and 141 on the top and bottom respectively connected to the top and middle conductive strips, and a holder or connector 133 and 135 on either side where the switch interfaces the dielectrics 121 and 125. The blumlein module can then be used for forming a particle accelerator, where several such modules are often stacked, as well as other application that need a pulsed, high-voltage energy source, such as a radar transmitter, for example.

In the embodiment of FIGS. 1 and 2, the bottom dielectric (111, 113, 115) and the top dielectric (101, 103) are taken to be of the same thickness and of the same material. More generally, other arrangement may be used, as may other geometries, but the shown arrangement is useful for discussing the various aspects presented below. More detail and other examples can be found in US patent publication number 2010/0032580 and U.S. Pat. Nos. 5,757,146; 5,511,944; and 7,174,485. More detail on a suitable switch 131 is described: G. Caporaso, “New Trends in Induction Accelerator Technology”, Proceeding of the International Workshop on Recent Progress in Induction Linacs, Tsukuba, Japan, 2003; G. Caporaso, et. al., Nucl Instr. and Meth. in Phys. B 261, p. 777 (2007); G. Caporaso, et. al., “High Gradient Induction Accelerator”, PAC'07, Albuquerque, June 2007; G. Caporaso, et. al., “Status of the Dielectric Wall Accelerator”, PAC'09, Vancouver, Canada, May 2009; J. Sullivan and J. Stanley, “6H—SiC Photoconductive Switches Triggered Below Bandgap Wavelengths”, Power Modulator Symposium and 2006 High Voltage Workshop, Washington, D.C. 2006, p. 215 (2006); James S. Sullivan and Joel R. Stanley, “Wide Bandgap Extrinsic Photoconductive Switches” IEEE Transactions on Plasma Science, Vol. 36, no. 5, October 2008; and Gyawali, S. Fessler, C. M. Nunnally, W. C. Islam, N. E., “Comparative Study of Compensated Wide Band Gap Photo Conductive Switch Material for Extrinsic Mode Operations”, Proceedings of the 2008 IEEE International Power Modulators and High Voltage Conference, 27-31 May 2008, pp. 5-8. Further examples of using such a switch in a high voltage, radio frequency opto-electric multiplies for charged particle accelerators is described in U.S. patent application Ser. No. 13/352,187.

Referring back to FIG. 1, the exemplary switch structure is light activated by laser light as supplied by the optic fibers 141 and 143 that are held on the sides of the switch 131 by the ferrules 137 and 139, respectively. The middle portion 113 of the bottom dielectric extends to the sides to help support the fibers 145 and 147 and can also serve a heat sink function. The upper conductive strip 101 and lower conductive strip 105 are electrically connected on the left side of FIG. 1. Several such blumlein modules can then be stacked to form an accelerator.

Unlike the arrangement of the blumleins described in the references cited above, where the switch structure is placed off to the end of the module, in the exemplary embodiments the switch is centrally placed between the top and middle conductive strips. Because of this difference, a brief description its operation will now be given. Referring to FIG. 1, assume that the accelerator is on the right side of the blumlein, or, more generally in the case of other applications, that the pulse to be presented on the right hand side. The one transmission line is the right “wing” of the top half (the dielectric 125 between the top conducting strip 101 and middle conducting strip 103 to the right of the switch module), and the second transmission line is the left “wing” of the top half of the left “wing” (to the left of the switch) plus the whole transmission line on the bottom (along dielectrics 111, 113, 115), which comprises the bottoms of the right and left “wings”. Initially the top and bottom conductive strips (101, 105) are at ground and the middle conductive strip 103 is at a high voltage. The switch is then turned on.

The pulse generated by the switch start moving in both directions away from the switch in the top transmission lines. The left wings of the top and of the bottom lines are connected by a low resistance, which can just a short connection between them; for example, the connection can go through a hole or metallized via through the body of the blumlein. Consequently, the pulse will continue to move back to the right in the “bottom” transmission line after it reaches the end at the left top line, but its electric field is now upside-down. The right ends of the bottom and the top transmission lines are not connected (there is a high resistance between them). Because of this, the pulse will be reflected when it reaches the right end of the right top transmission line and start moving towards the switch. When this reflected pulse reaches the switch (that is still open, so its resistance is low), the pulse will be reflected again but with 180 degree shifted phase, which means that its polarity will be opposite (its electric field turned over also). The second time reflected pulse will be moving toward the accelerator and will get the accelerator at the same time when bottom pulse will get there. Sum of these two pulses will make a pulse with a double voltage amplitude.

Under the arrangement of FIGS. 1 and 2, the switch 131 is itself placed between top conductive strip and the central conductive strip. Consequently, the switch is subjected to high electric field values. As the dielectric constant of the switch will typically not match that of the adjoining dielectric material, this can lead to charge accumulation at the interface between these. This problem is considered in the following section. For a light activated switch, such as that of the exemplary embodiment, another problem is that the ferrules used to provide the illumination source also need to be able to handle the high field levels while still providing sufficient light. The arrangement of the ferrules is then considered in a subsequent section.

Blumlein with Encapsulated Solid-State Switch

This section considers in more detail some techniques for building blumlein devices where materials bonded together and whose interface operates under very high electrical fields, over 30 kV/mm for example. The weakest part of high voltage devices is often an interface between bonded materials with different dielectric constants. Electrical charge tends to accumulates at the interface, due to difference in permittivity of joint media and due to local high electrical fields created by imperfections at the interface. The higher electrical field, which is produced by the extra charge, and higher charge mobility along the interface, increase the probability of the electrical breakdown through the interface. The methods described here minimize these problems and allow for the building of blumlein devices with encapsulated solid state switches.

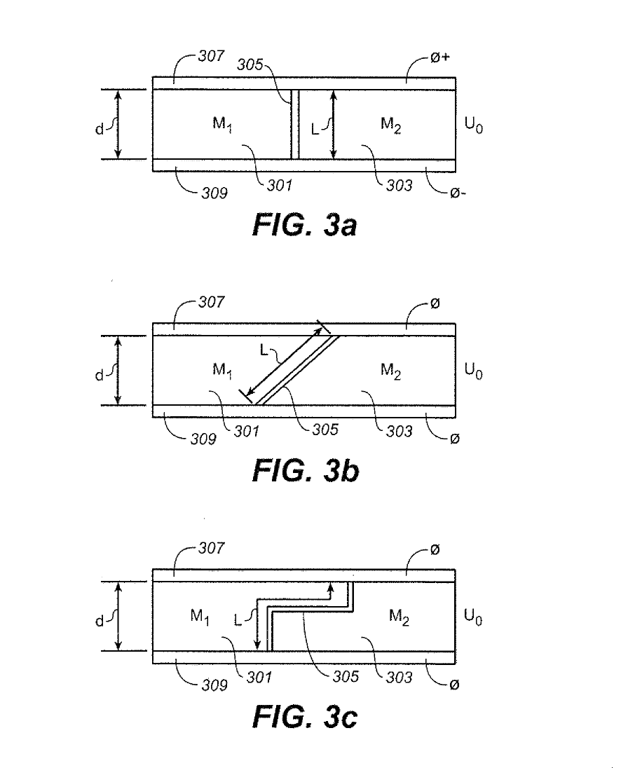

Considering the problem itself further, FIG. 3a shows the interface 305 of length L between bonded materials M1 301 and M2 303, which is inserted into electrical field E=Uo/εd, where ε is an effective permittivity at the interface 305, that is created by powering the metal contacts/terminals on top plate 307 and at the bottom plate 309 of the device that are separated by a distance d to a voltage difference of Uo. Here M1 301 and M2 303 respectively correspond to the dielectric 121 and the switch 131 of FIGS. 1 and 2. In a typical implementation, d may be on the order ˜1 mm and Uo may 25 kV up to 100 kV. The interface boundary 305 is orthogonal or normal to the surface of the upper and lower plates (307, 309), so that d is the same as L. In this case, the electrical field along the interface is the same as it is across the body of the device. Dielectric materials can usually be optimized for high voltage applications and there are number of available materials that can withstand electrical fields over 30-100 kV/mm. In the exemplary embodiments the body of the switch is formed a semiconductor, specifically silicon carbide, so that there will typically be a mismatch between the permittivity between it and the dielectric of the blumlein transmission line.

The simple interface arrangement shown in FIG. 3a can usually withstand electrical fields only up to about 10 kV/mm. To withstand higher values, the exemplary embodiments use developed interfaces between bonded materials. FIGS. 3b and 3c present examples of such developed interfaces, where the first of these has a diagonal interface 305′ and the second a stepped interface 305″. Preferably, the sharp corners in an arrangement such as FIG. 3c are rounded somewhat, but this is usually obtained as a result of fabricating process. In either of these cases, the effective electrical field along the interface is E=Uo/εL, so that the ability of the interface to withstand high voltages is improved by this increasing the interface length L by having at least a portion of the interface running in a direction that is non-orthogonal between the conducting surfaces.

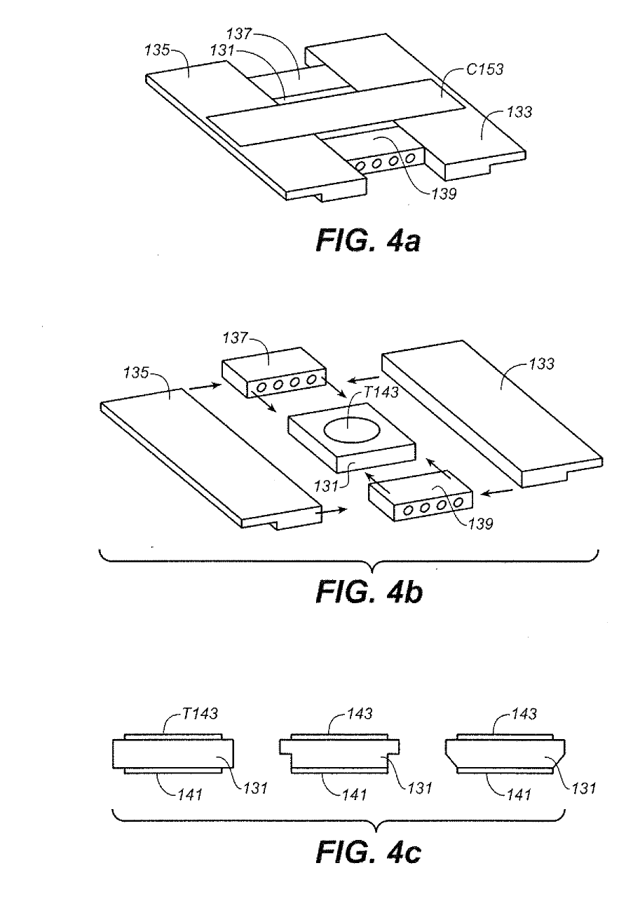

The exemplary switch used here is an optically activated semiconductor switch formed largely of silicon carbide, but in other embodiments could be of a semiconductor material, such as GaN, AlN, ZnSe, ZnO, diamond, doped glasses, semiconductor particles/crystallites embedded into insulator materials, and so on. For any of these, there will typically be a resultant mismatch in permittivity between it and the adjacent dielectric used in the blumlein's upper transmission line. Such a switch will often come rectangularly shaped, more or less, so that if directly bonded to the dielectric it would present the sort of cross-section shown in FIG. 3a. As the switch itself may not readily be shaped (or reshaped) to have a different profile, rather than have the switch directly adjoining the dielectric, a connecting structure, or carrying unit, is used as part of the switch module for this purpose. The formation of a switch module is illustrated with respect to FIGS. 4a and 4b.

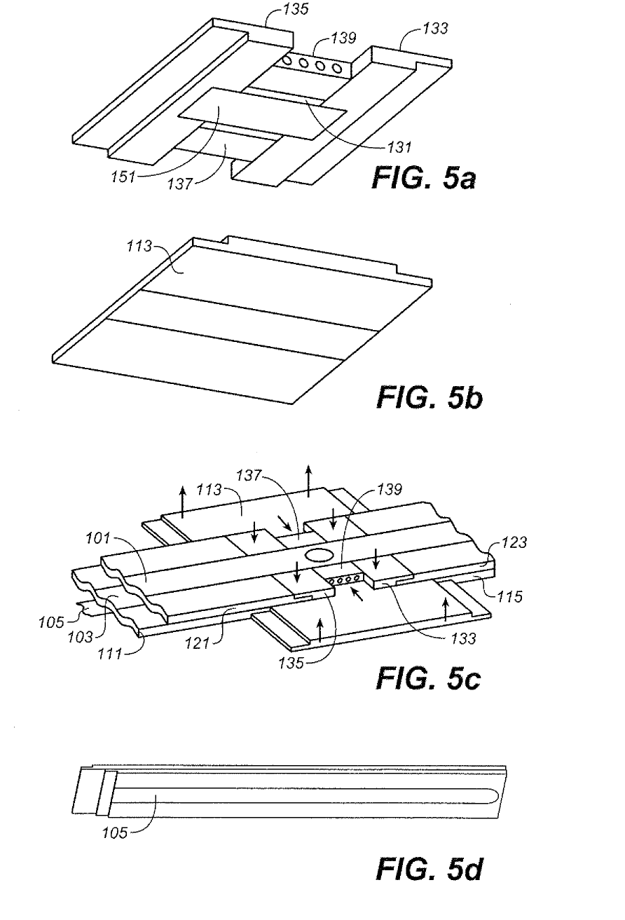

FIG. 4a shows an assembled switch module structure for the opto-switch 131 to be placed into the blumlein and FIG. 4b shows an exploded view of the elements. The module includes the connectors 135 and 133 and the ferrules 139 and 137. The ferrules 137 and 139 can be used to maintain optical fibers for triggering the switch as well as for a heat sink. The optical fibers, and hence the ferrules, are discussed further in the next section and are used as the exemplary switch 131 is optically activated, but would not be required in other embodiments where the switch 131 is otherwise activated. In this particular version, which corresponds to the embodiment of FIGS. 1 and 2, the connectors 133 and 135 and ferrules 137 and 139 are separately elements, but in other embodiments (such as discussed further below) they can be a solid unit instead of using an assembly. The overall dimensions of units 133, 135 and 137, 139 can vary depending on particular design. The solid state switch 131 has with terminal T 143 and a similar terminal 141 on its underside. Once the elements shown in FIG. 4b are assembled contacts C 153 and a similar contact (151, see FIG. 5a) on the bottom can be added to the module assembly, as shown in FIG. 4a. The module contacts are here plated after module has bonded. (In FIG. 2, the contact C 153 is not shown separately, but can be taken as part of the upper conducting strip 101, with the bottom contact similarly incorporated into the middle strip 103.)

The side portions 133 and 135 of the module can be formed of a material having a permittivity close to that of the switch material. For example, these could be made of epoxy, as could the ferrules 137, 139. Because of this, although the profile of the switch 131 may result in the interface between it and the connectors 133 and 135 being as in FIG. 3a, the relatively similar permittivity values shift the problem to the interface between the connectors 133 and 135 and the dielectric of the transmission, such as 121 and 125, respectively, in FIGS. 1 and 2. As both the connectors and the dielectric will usually be able to have their shapes easily formed into more arbitrary shapes than the switch, the can have an elongated interface having a portion that is substantially non-orthogonal to the conducting surfaces, such as those shown in FIGS. 3b and 3c.

Although the discussion here is for the encapsulation of a switch within a blumlein structure, the same technique can similarly be applied to other cases where two elements need to have an interface between to such conductors at a high voltage difference, but have differing permittivity values. For the element with a relatively short interface between the plates, another material having a relative similar permittivity can be introduced to allow this interface to withstand higher field values. The other element can then have its interface with introduced connecting material shaped to increase this interface that will then have the greater discontinuity in permittivity values. Additionally, although the profile of the switch 131 in the example is taken to be like that on the left of FIG. 4c, it may have other profiles, with examples shown center and right. In these case, although the shape of the switches will allow them to withstand higher field levels and remove the need for the elements 133 and 135 of the module, the use of such connectors can be to further increase the field strengths the interface can handle, both further lengthening the interface and also splitting up the amount of transition in relative permittivity change over two transitions. Aside from these considerations, the use of such a module can be useful for placing the switch within the blumlein as silicon carbide does not readily bond to many other materials.

FIG. 5a is a down-up view for the same module assembly as in FIG. 4a. This module can then be inserted into a blumlein and the whole assembly coupled optical fibers F 145 and 147, as shown in FIG. 1. It also includes a heat sink unit/support 113 as shown in FIG. 5b, which includes a portion of the bottom conductive strip 105, and two blumlein wings as shown in FIG. 5d. One example of the assembling procedure is shown in FIG. 5c: first, the ferrules 137 and 139 are bonded to the switch, followed by bonding units 133 and 135 to the assembly. Then module can bonded to the blumlein wings. After that, electrical contact between module contacts and blumlein strip lines have to be established. It is important that the assembly allows access to the top and middle strips of the blumlein to complete formation of the upper and middle conductive strips 101 and 103. After this is the bonding of the heat sink unit 113 to the assembly, followed by making electrical contact between bottom strip of the heat sink unit 113 and bottom strips of the blumlein to complete the bottom conducting strip 105.

### Optical Coupling of Switch to Light Source

As noted above, the exemplary embodiment of a blumlein structure uses a light activated switch. This section considers the coupling of the illumination to the switch. Although the exemplary embodiment uses the side connector structures 133 and 135 discussed in the last section as well as the ferrules 137 and 139 discussed in this section, more generally, these as independent aspects. For example, the switch may be light activated, but not require the connector structures 133 and 135; conversely, these side connectors can be used for switch that is activated by other means not requiring the optic fibers.

To activate the switch, it needs to be sufficiently illuminated. This can be done by use of the ferrules, placed on either side of the switch, holding optical fibers so that they optically couple to the switch. The other ends of the fibers could then be illuminated by a laser, for example, to effect turning the switch on and off. The amount of light on the switch will then be based on the number of fibers, their cross-sections, and the intensity of the light. As the ferrules with be subjected to the field between the upper and middle conductive strips of the blumlein, they will need to be able to support this field without breaking down. The more space given over to the optical fibers, the less field it will be able to support. On this basis, it makes sense to reduce the number, cross section, or both, of the fibers; however, this would require an increase in the intensity of light. Also, having too many fibers increases the complexity of the design. As the switch can only withstand a certain level of fluence, or light energy per area, on its surface before the switch is damaged, the intensity of the light must be balanced against the number and size for the fibers. Similarly, although increasing the width of the conducing strips can provide a larger pulse from the blumlein, this will place more of ferrules under a higher field. Consequently, a number factors need to be balanced when optimizing the design.

As shown in FIG. 4b, for example, the ferrule portions 137 and 139 of the switch module assembly has several holes for the insertion of the optical fibers, shown as 145 and 147 in FIG. 1. Although larger openings would allow for larger fibers, and correspondingly more illumination on the switch 131, this would make the ferrules breakdown at lower field strengths. (In the example, the openings are round, as this shape is useful when round optic fibers are used, but rectangular or other shaped openings could also be used.) In one of the principle aspect of this section, top and central conducting strips are formed so that the switch is allowed to extend laterally to either side before the interface with the ferrules, allowing a margin so that ferrules are not placed directly between the plates. Although the ferrules still be subjected high filed levels, this will reduce it below the full strength between the plates. As to the width selected for the conductive, this is again a design choice as the wider the conductive strips, the stronger the pulsed that can be produced, but a wider strip then makes the ferrules more likely to break down.

In the exemplary embodiment for the switch module described with respect to FIGS. 4a and 4b, the ferrules 137 and 139 each hold four fibers; and although the figures are not fully to scale, the do illustrate the relative size of the openings to the ferrule as a whole. Any bonding agent for the fibers to the switch would need to be transparent. The exemplary switch is formed of silicon carbide. As the fibers cannot be readily bonded to this material, the ferrules are used to mechanically the bond the fibers by holding them up to the switch. The ferrules can be made of the same material as the side pieces 133 and 135, such as epoxy. In the embodiments discussed so far, the side pieces 133, 135 and ferrules 137, 139 are formed separately and then joined together. This is convenient for discussing the independent aspects associate with each of this elements and although it is preferred in some applications, in other cases it is preferable that these elements of the switch module are formed of a single piece. Such a unified embodiment for the switch holder is discussed in the next section.

Single Piece Holder with Ferrules

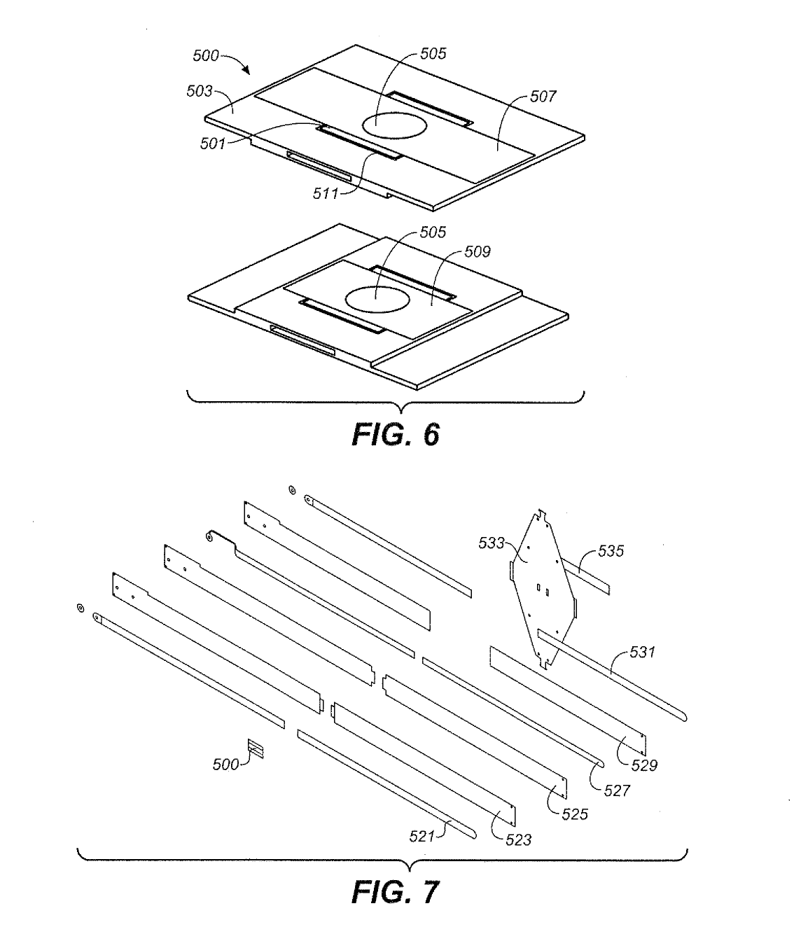

FIG. 6 shows a top and bottom view of switch module 500 respectively at top and bottom. The silicon carbide (or other semiconductor) switch 501 is placed into the monolithic dielectric switch carrier 503. Here the holder 503 includes both the shape having a non-orthogonal ends where it will interface with the dielectric and a set of 6, in this version, openings for optic fibers on each of the sides. In other embodiments, if the switch is not light activated, the holder need not have the ferrule function and the holes could be eliminated and, if desired, the conductive strips could be widened; conversely, if the elongated end profile is not needed due to mismatch in permittivities, the ends could be square will the holder would still perform the ferrule function. The space between the switch 501 and holder 503 can then be filled in with epoxy or other filler 511. The a portion 507 of the top conductive strip and a portion 509 of the bottom conductive strip run along the outside of the module are formed of, for example, copper. The contact terminals are shown at 505 for illustration purposes, although these are actually below the strips 507 and 509.

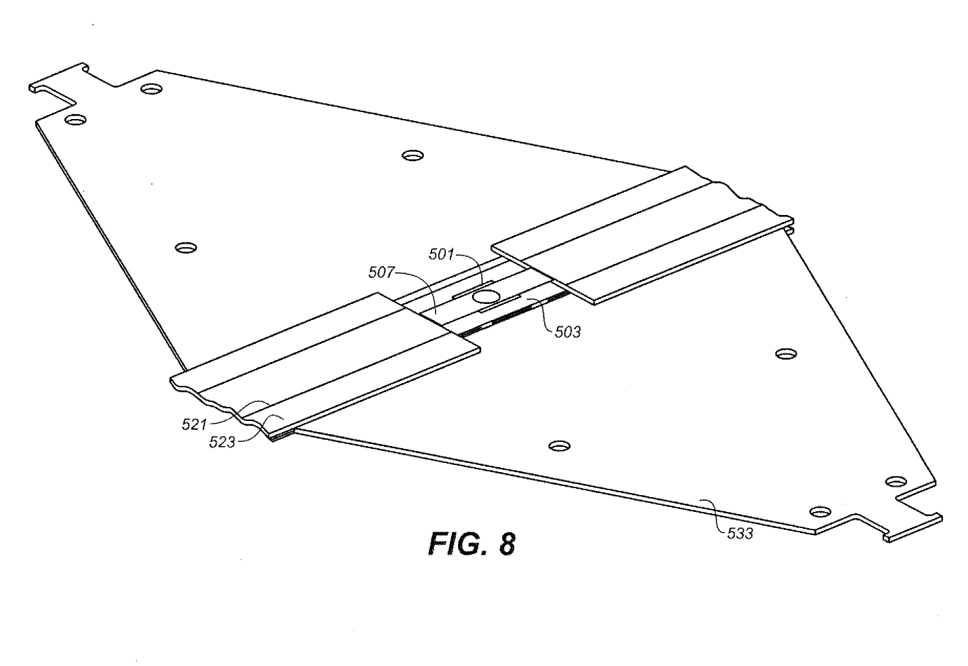

FIG. 7 shows an exploded view of a blumlein structure for this embodiment. The top portion 507 of the conductive strip of the switch module assembly is connected to the rest of the top planar conductive strip 521 having left and right portions and which can again be made of copper or other conductor. The top dielectric strip 523 again has left and right wings and can be made of Cirlex® or kapton, for example. In this embodiment, a bonding layer 525 is then between the top dielectric strip 523 and the middle planar conductive strip 527, where each again has left and right portions and the thin dielectric buffer layer 525 can be applied to bond layers such 523, 527 and 529 together. The middle planar conductive strip wings can again be of copper or other conductive material and will connect together through the bottom contact strip 529 of the switch module. The bottom dielectric layer is formed of the dielectric strip 531, again with two wings, and a central portion made of the support 533, where these could again be of Cirlex® or kapton, for example. The bottom planar conductive strip can again be of copper or other suitable conductor and is here formed of a first part 531 of left and right wings and also a middle piece 535 for under the support 533. Rather than have a single piece for the bottom semiconductor layer, it is often convenient to use the support 513 as this can support the fibers as they feed into the ferrules, as well as being useful for mounting the blumlein modules and serving a heat sinking function. The central portion of the blumlein structure when assembled is shown in an enlarged view in FIG. 8. The embodiment in FIGS. 7 and 8 is again evenly spaced between the pairs of conductors, symmetric in that the switch is centrally located, and uses the same material for the dielectrics in both the top and bottom transmission lines, but other embodiment can use other arrangements for any of these.

The various aspects described above are presented further in U.S. patent application Ser. No. 12/963,456.

### Switch Placement

This section considers the geometry of the blumlein and how the switch is placed within the blumlein structure. The thicker the switch, the higher the voltage it charged to without breaking down. A thicker switch can also provide a larger surface to illuminate. Although the sort of improvements described in U.S. provisional application No. 61/680,782 can increase both the voltage that can placed across the switch and also improve the optical response of the switch, being able to have a thicker switch can make for a better blumlein. (The next section also considers illumination.) On the other hand, the thinner the blumlein, the higher the electric field it can provide and the thinner a stack of blumleins, such as used in an accelerator, can be. This section considers a technique to overcome these two seemly contradictory aims by presenting a way to fit a thick switch into a thin blumlein. By combining the two, thin blumleins can be charged to high voltages and achieve very high accelerating gradients by gaining from both higher a charge voltage as well as the higher electric field and therefore produce a very compact accelerator.

The exemplary embodiments in the following discussion of this section will again be based on the sort of optically activated switch discussed above, although other forms of solid state switch could be used. The various other aspects also described above are also complimentary in that although they can be combined with the aspects of this section, the techniques of this section can also be used independently of them.

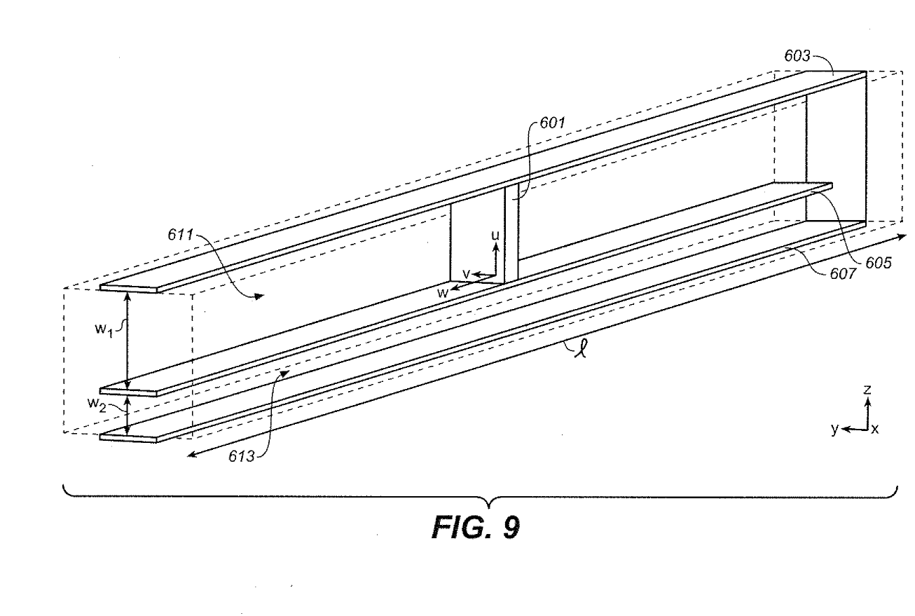

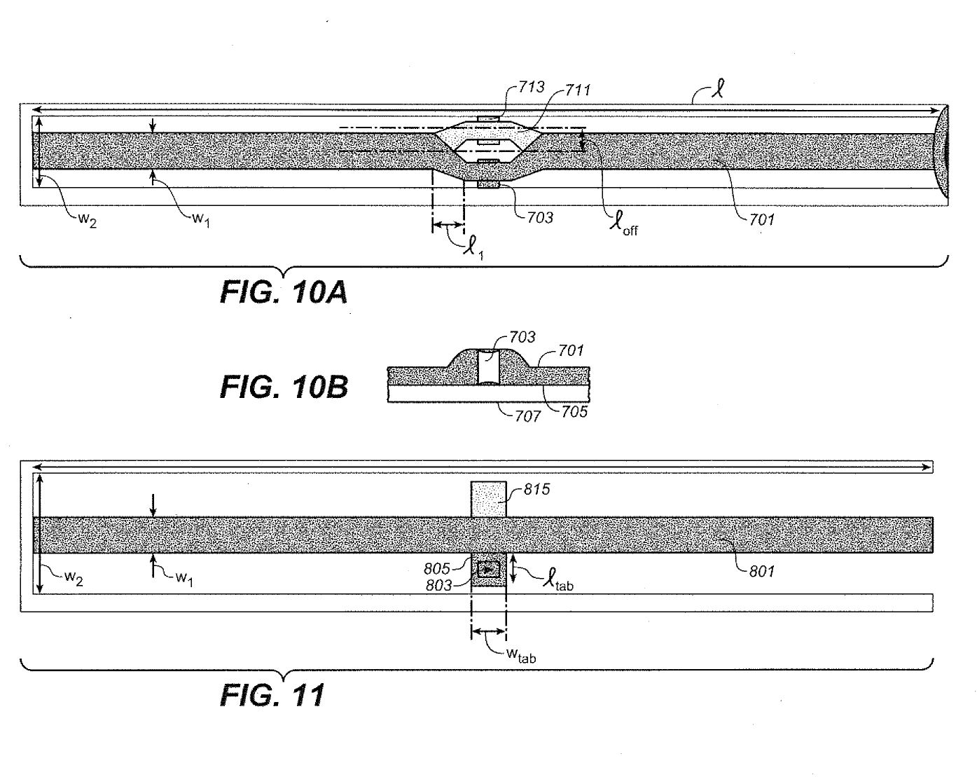

FIG. 9 illustrates some of the relevant elements of a blumlein. Here the optical connections and other feature of the switch module are suppressed to simplify the discussion. The switch 601 is placed between the top conductor 603 and middle conductor 605, where the rest of the space in between is filled with the dielectric 611. The bottom conductor is shown at 607, with the space between it and the middle conductor 605 filled with dielectric 613. The top conductor 603 and bottom conductor 607 are then connected at on end (here on the right) and then can be grounded at the other end. Here the blumlein is a length l with a switch is located at the center. The top dielectric layer 611 has a width w₁, which is wider than the lower dielectric 613 with a width w₂, in order to allow for a thicker switch, but at the cost making the blumlein wider. The width of the blumlein can be decreased by squeezing it down away from the switch, so that it is narrowing at the ends; but this does not allow for multiple such blumleins to be stacked any more closely. If these switches are displaced to the side, but not all at the same point, then the individual blumleins can be stacked. Examples of this are illustrated in FIGS. 10 and 11.

FIGS. 10a and 10b illustrate a first exemplary embodiment for displacing the switch modules to the sides of the of the blumlein structures in a “necking” arrangement. FIG. 10a shows this arrangement from above. The top conductor 701 of the top-most blumlein stack is shown along with the switch 703, with the rest of the top-most blumlein underneath. The switch region curves out a distance to the side (downward in FIG. 10a). The next blumlein down in the stack is displaced the other direction, where the top conductor 711 and switch 713 can be seen. The stack of blumleins can then alternate sides, allowing for the switch region to each have a greater thickness. FIG. 10b shows an example of this in a side view of the top most blumlein, where the middle conductor 705 and bottom conductor 707 are straight, while the top conductor 701 bulges upward, for example, to hold a thicker switch 703.

In FIG. 10a, each of the blumleins has total length l and the switch region curves outward of over a length l₁ for a displacement l_{off}. Taking into account the offsets, for blumleins of a width w₁ of this makes for a width of w₂. In the example of FIG. 10a, the sideways displacements are all of the same amount l_{off} and are all the same distance along the blumleins at the center. More generally, differing amounts of sideways displacement can be used for the different blumleins displace to each side, allowing for more access to the switches. (This could be used to provide easier access to the top or bottom of the switches, such as could be used in the sort of illumination arrangement described in U.S. provisional application No. 61/680,782.) Alternately, or additionally, the offset can be displaced at differing locations along the length of the blumleins.

FIG. 11 illustrates a second exemplary embodiment for displacing the switch module to the side of the of the blumlein structure. In FIG. 11 a tab structure is used: the top, middle and bottom conductors are all straight, but the top and middle conductors each include tabs, between which the switch is placed. As the bottom conductor is not connected directly to the switch contacts, it does not need to have the tab. FIG. 11 again shows a top view, where the top blumlein's top conductor 801 has a tab 805 of width w_{tab} and length l_{tab}, under which is the switch 803. The tab of the next blumlein down is at 815, where the tabs can alternate sides down the stack. This again allows for a thicker switch. The tabs of FIG. 11 are shown to be symmetric between the two sides, all with the same sideways displacement, and all centrally located, but as with the embodiment of FIG. 10a different amounts of displacement can be used for different blumleins down the stack, both to the sides and down the length of the blumlein.

Altering of the geometry of the blumleins to place the switches off the to the sides, as in FIGS. 10a and 11, can decrease the efficiency of each blumlein, in terms of the amount of maximum electric field that can be generated for a given voltage, this is more than offset by being able to use a higher voltage across the switch and to be able to have shorter stack of blumleins.

### Improvements for Switch Illumination

This section looks at techniques for illuminating the optically activated switches, such as those used in the exemplary embodiments above. This section is specific to opto-switches, but is complimentary to other aspects described above, in that it can be combined with them or used independently. For example, although this discussion is given here mainly in the context of the switch as part of a blumlein structure, the techniques described in the following can be applied in other contexts where such switches are used. For example, other applications could include radar, EUV sources, nuclear fusion experiments, waste-water treatment, and so on. Within the blumlein context, the illumination methods of this section can be advantageously used with the sorts of geometries described in the last section where they can used in a compact particle accelerator, for example.

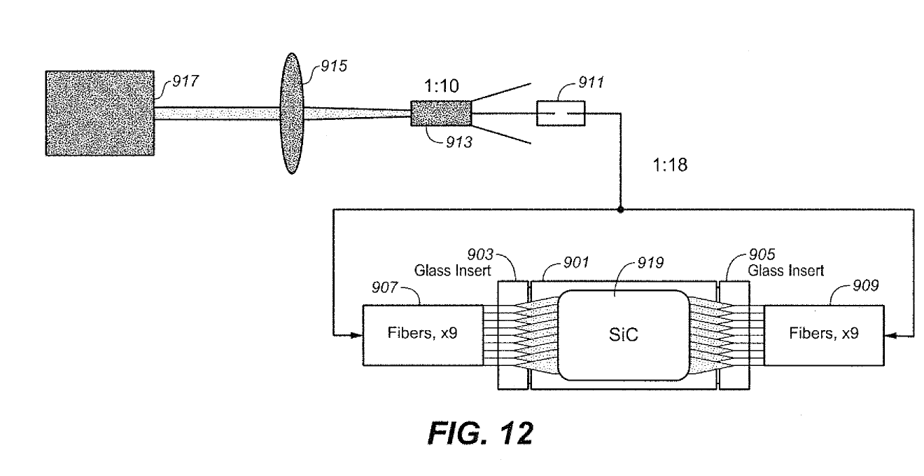

FIG. 12 schematically illustrates some of the elements in the illumination path. Here the switch 901 is illuminated from both sides, such as in FIG. 1, but the other elements are not shown to simplify the discussion. Nine fibers 907, 909 are fed in from each side into the glass inserts 903, 905 to illuminate the switch, which the sort of silicon carbide (SiC) switch described above. The light source is a high intensity laser 917 whose beam is sent through a focusing lens and then split at fiber beam splitter 913 and again at fiber beam splitter 911 to supply all the switches. Here the view is from above, showing the metallized area 919 formed on the SiC crystal More generally, the illumination of the switch can be from any of the facets of the switch; and although the exemplary embodiment provide the illumination from the source using fibers, it can be delivered through other mechanisms of through free space.

How effective the illumination is depends on the amount of laser energy incident on the switch, how this light from the source is distributed on switch, its uniformity, and how much of the light is absorbed. The density of light energy that can be applied to the switch may be limited by how the of incident light energy that switch and the intermediate elements can take without being damaged. It could also be limited based on the amount of power the laser can generate. This section looks at ways of improving illumination despite such limitations; and even when which such considerations are not limiting, it generally better to improve efficiencies when possible.

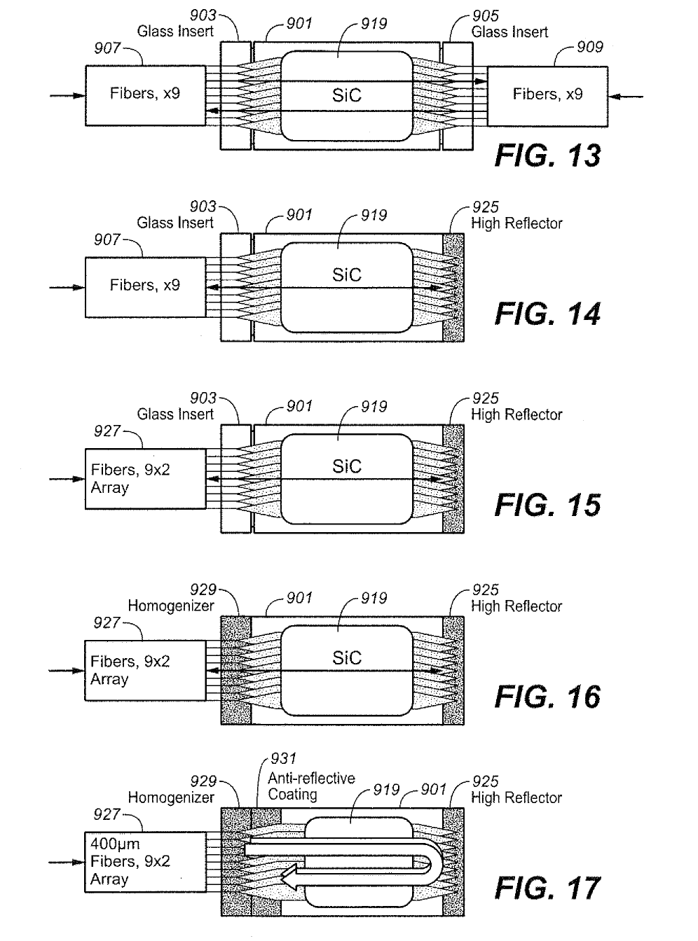

FIG. 13 is a detail for the switch module of FIG. 12 to further illustrate the illumination process. The sets of, here, nine fibers 907, 909 are connected into the glass inserts 903, 905 to illuminate the switch when the light source is active. As shown, the light is incident upon both sides of the switch body, but, as supplied from the fibers, the light is not spread uniformly across the switch body and a significant portion of the light will pass through the switch body without being absorbed.

FIG. 14 illustrates a first way to improve absorption. As shown in FIG. 14, the illumination now only incident from one side, but the side opposite now has a reflective surface 925 to reflect back any light that transvers the switch body, effectively doubling the lights path and increasing the amount absorbed. The high reflector 925 could be a separate element or a coating at laser wavelength, such as a dielectric material, applied directly on to the switch body. In either case, absorption is increased, improving system efficiency. This also allows the switch to be efficiently illuminated from only a single side and can also reduce the number of reflective and scattering surfaces.

As the one side with the high reflector is no longer using illumination, additional illumination can be supplied on the side opposite. For example, if the switch can handle the additional light energy, additional fibers can be connected at the side opposite the high reflector. This is shown at 927 in FIG. 15 where, for example, two or even three layers of fibers at attached at the right hand side of the switch module. This arrangement can be particularly useful when a larger switch can be used, such as under the arrangement as described in the last section. Having more fibers can also provide more uniform illumination across the face of the switch body.

To further improve illumination uniformity on the face of the switch, a homogenizer can be used as shown at 929 of FIG. 16. For example, a micro-lens array can be used. If the SiC crystal, which has an index of refraction of about 2.7 has a width of, say, 12 mm, a micro-lens with a focal length (in air) of something like 1 mm could provide for the beam to not have any hot spots in the switch body. The use of a relatively long focal length in this was allows for the illumination reasonable well columnated. Additionally, the use of a homogenizer means that the switch module is not as sensitive to the alignment of the incoming light, whether from a set of fibers or other source, such as reflected off a prism used when access to the side to be illuminated is restricted.

Any of the embodiments described so far can further benefit by the inclusion of an anti-reflective coating on the facet from which the light is incident. FIG. 17 adds such an anti-reflective coating 931 to the embodiment of FIG. 16. Although this shows the anti-reflective coating 931 combined with a high reflective coating 925, it can be used separately. Both of the anti-reflective coating 931 and the high reflective surface 925 can help to reduce Fresnel reflection loss. The anti-reflective coating may also be used to help protect the optical fibers by eliminating sub-cavity effect between the fiber tips and the switch face.

Additionally, the gaps in the optical components, such as from the fiber tips to the switch, can be filled with silicon oil. Firstly the oil avoids the any local breakdown due to high electrical field. Secondly, the refractive index of the oil can match that of the fiber's glass and lens, so that it reduces the Fresnel reflection loss. Also, pulling the fiber back some distance, such as a few millimeters (say about 3 mm, or, more generally in the 1-5 mm range), can enhance coupling efficiency into the silicon carbide and avoid damage of the fiber fingers, inside the silicon carbide, or both due to possible sub-cavity effects and focusing effects. This can be very effective in protecting the fibers at high laser energy coupling processes.

The ability to effectively illuminate the switch from only a single side can help to significantly reduce the size of the blumlein. Although switching to single side illumination by itself can reduce uniformity, any increased non-uniformity can be reduced by the other techniques presented here. Both of the high reflector and the anti-reflective coating can improve energy absorption. The fiber array arrangement can provide for a more uniform light source distribution and the homogenizer can also provide for more uniform illumination. Together, these changes can significantly improve absorption. Further improvements can include a free space beam split rather than the arrangement of FIG. 12.

Referring back to the preceding section on Switch Placement, this described ways of displacing the switches to the side of the blumlein, allowing for a larger switch to be incorporated and also allowing for more options on which sides of the switch can be illuminated. As a number of sides are now more readily accessible, the different blumleins in the stack can be illuminated from different sides, allowing for further compaction of the structure; and by providing a larger switch face that can be illuminated, a higher energy source can be used without the switch breaking down.

### Conclusion

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application, to thereby enable others skilled in the art to best utilize the invention in various embodiments and with various modifications as are suited to the particular use contemplated. It is intended that the scope of the invention be defined by the claims appended hereto.

It is claimed:

1. A structure comprising one or more blumlein structures, each of the one or more blumlein structures including:
a first conductive strip;
a second conductive strip;
a third conductive strip, where the second conductive strip is positioned between the first and third conductive strips and, outside of a first region, the first, second and third conductive strips are parallel to one another along a first axis;
a first dielectric;
a second dielectric that fills the space between the second and third conductive strips; and
a switch module including a switch having a first terminal and a second terminal respectively connected to the first and the second conductive strips,
wherein the first dielectric and the switch module are joined together to fill the space between the first and second conductive strips, and
wherein the switch is located in the first region between the first and second conductive strips, being displaced sideways relative to the first axis.

2. The structure of claim 1, wherein the first regions of the first and second conductive strips each include a tab extending sideways, the switch being located between the tabs.

3. The structure of claim 1, wherein in the first regions of the first, second and third conductive strips are each displaced sideways relative to the first axis.

4. The structure of claim 1, wherein in the first region in which the switch is located, the first and second conductive have a greater separation than outside of the first region.

5. The structure of claim 1, wherein the structure includes a plurality of the blumlein structures stacked on upon the other in a direction perpendicular to the first axis, and wherein the blumlein structures of the stack alternate the side to which the corresponding switch is displaced.

6. The structure of claim 5, wherein the blumlein structures of the stack include a plurality of corresponding switches displaced by differing amounts to at least a first of the alternating sides.

7. The structure of claim 5, wherein the blumlein structures of the stack include a plurality of corresponding switches displaced by differing amounts along the direction of the first axis.

8. The structure of claim 5, wherein the structure is part of a particle accelerator.

9. The structure of claim 1, wherein the first regions is centrally located along the direction of the first axis with the blumlein structure.

10. The structure of claim 1, wherein the switch is an optically activated switch and each of the one or more blumlein structures further includes:
an illumination element arranged to provide illumination from a light source incident upon a first side of the switch.
